(19) United States
(12) Patent Application Publication
(10) Pub. No.: US 2021/0043124 A1
(43) Pub. Date: Feb. 11, 2021

(54) GATE DRIVER CIRCUIT AND DRIVING METHOD OF DISPLAY PANEL

(71) Applicant: HANNSTAR DISPLAY CORPORATION, Taipei City (TW)

(72) Inventors: Cheng-Yen Yeh, Taichung City (TW); Guang-Shiung Chao, Tainan City (TW); I-Hsuan Chen, Kaohsiung City (TW)

(21) Appl. No.: 16/942,736

(22) Filed: Jul. 29, 2020

(30) Foreign Application Priority Data
Aug. 8, 2019 (CN) 201910731796.0

(51) Int. Cl. G09G 3/20; G11C 19/28

(52) U.S. Cl. CPC G09G 3/20; G11C 19/28; G09G 2310/0286; G09G 2300/0819; G09G 2310/06

(57) ABSTRACT

The present invention provides a gate driver circuit, and a shift register of the gate driver circuit includes a precharge unit and a pull-up unit. The precharge unit receives a first input signal and a second input signal and includes a first transistor and a second transistor. A first terminal of the first transistor receives a first input signal, a gate of the first transistor is coupled to the first terminal of the first transistor, and a second terminal of the first transistor is coupled to the first node. A first terminal of the second transistor receives the second input signal, a gate of the second transistor is coupled to the first terminal of the second transistor, and a second terminal of the second transistor is coupled to the first node. The pull-up unit receives a first clock signal and outputs a scan signal.

### CROSS REFERENCE TO RELATED APPLICATION

This application claims priority of China Application No. 201910731796.0, filed on Aug. 8, 2019. The entirety of the above-mentioned patent application is incorporated by reference herein and made a part of this specification.

### BACKGROUND OF THE INVENTION

### 1. Field of the Invention

The present invention relates to a gate driver circuit and a driving method of a display panel, and more particularly, to a gate driver circuit and a driving method of a display panel which can reduce the space occupied by the gate driver circuit in a peripheral region.

### 2. Description of the Prior Art

A display panel is formed by two substrates and a plurality of layers with various electrical components disposed between the two substrates to perform image display function. Since display panels are thin and light, have low power consumption and no radiation pollution, they are widely used in various portable or wearable electronic products such as notebooks, smart phones and watches, as well as vehicle displays, to provide more convenient information transmission and display.

The width of the frame of the display panel is continuously reduced according to requirements, and the space for disposing circuits in the peripheral region is reduced as well. Therefore, the structure of the gate driver circuit must be simplified for accommodating thin film transistors used for outputting signals with large enough sizes in such limited space, and overcoming the problem of insufficient voltage or driving power when these thin film transistors are driving gate lines.

### SUMMARY OF THE INVENTION

The present invention provides a gate driver circuit and a driving method of a display panel to solve the above technical problem, in which the space occupied by the gate driver circuit in a peripheral region can be reduced, thereby reducing the frame width of the display panel.

To solve the above technical problem, the present invention provides a gate driver circuit used for driving a display panel. The gate driver circuit includes a plurality of shift registers sequentially outputting a plurality of scan signals to the display panel, in which an i^{th}-level shift register includes a precharge unit and a pull-up unit. The precharge unit is used for receiving a first input signal and a second input signal and controls an electric potential of a first node according to the first input signal or the second input signal. The precharge unit includes a first transistor and a second transistor. A first terminal of the first transistor receives a first input signal, a gate of the first transistor is coupled to the first terminal of the first transistor, and a second terminal of the first transistor is coupled to the first node. A first terminal of the second transistor receives the second input signal, a gate of the second transistor is coupled to the first terminal of the second transistor, and a second terminal of the second transistor is coupled to the first node. The pull-up unit and the precharge unit are coupled to the first node, the pull-up unit receives a first clock signal and outputs an i^{th}-level scan signal from a second node according to the electric potential of the first node and the first clock signal, and i is a positive integer greater than or equal to 1.

To solve the above technical problem, the present invention provides a driving method of a display panel. Firstly, a gate driver circuit is provided, and the gate driver circuit includes a plurality of shift registers, and an i^{th}-level shift register includes a precharge unit and a pull-up unit. The precharge unit is used for receiving a first input signal and a second input signal and controls an electric potential of a first node according to the first input signal or the second input signal. The precharge unit includes a first transistor and a second transistor. A first terminal of the first transistor receives the first input signal, a gate of the first transistor is coupled to the first terminal of the first transistor, and a second terminal of the first transistor is coupled to the first node. A first terminal of the second transistor receives the second input signal, a gate of the second transistor is coupled to the first terminal of the second transistor, and a second terminal of the second transistor is coupled to the first node. The pull-up unit and the precharge unit are coupled to the first node, the pull-up unit receives a first clock signal and outputs an i^{th}-level scan signal from a second node according to the electric potential of the first node and the first clock signal, and i is a positive integer greater than or equal to 1. An initial signal is set as the first input signal, and a second-level scan signal output by a second-level shift register is set as the second input signal when i is 1. A (i−1)^{th}-level scan signal output by a (i−1)^{th}-level shift register is set as the first input signal and a (i+1)^{th}-level scan signal output by a (i+1)^{th}-level shift register is set as the second input signal when i is any positive integer from 2 to (N−1), so that the shift registers sequentially output a plurality of scan signals to the display panel, and N is a positive integer greater than 2.

In the gate driver circuit and the driving method of the display panel of the present invention, each level of the shift registers is electrically connected to the shift register of the previous level and/or the shift register of the subsequent level, or each level of the shift registers receives the scan signal of the previous level and/or the scan signal of the subsequent level. Therefore, in the gate driver circuit of the present invention, the number of connecting wires between the shift registers of different levels or the times of the connecting wires required to cross with each other can be reduced, so that the layout of the connecting wires can be simpler, or the space occupied by the connecting wires can be decreased, thereby reducing the width of the peripheral region. In addition, each level of the shift registers in the present invention includes eight thin film transistors. Therefore, the space occupied by the gate driver circuit of the present invention is relatively small, thus the width of the peripheral region can be reduced.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic diagram illustrating a display panel of a first embodiment of the present invention.

FIG. 2 is a schematic diagram illustrating a gate driver circuit of the first embodiment of the present invention.

FIG. 3 is an equivalent circuit diagram of an i^{th}-level shift register in the gate driver circuit of FIG. 2.

FIG. 4 is a timing diagram of the gate drive circuit of FIG. 2.

FIG. 5 is a schematic diagram illustrating a gate driver circuit of a second embodiment of the present invention.

FIG. 6 is a timing diagram of the gate drive circuit of FIG. 5.

FIG. 7 is a schematic diagram illustrating a gate driver circuit of a third embodiment of the present invention.

FIG. 8 is a timing diagram of the gate drive circuit of FIG. 7.

### DETAILED DESCRIPTION

To provide a better understanding of the present invention to those skilled in the technology, preferred embodiments will be detailed as follows. The preferred embodiments of the present invention are illustrated in the accompanying drawings with numbered elements to elaborate on the contents and effects to be achieved. It should be noted that the drawings are simplified schematics, and therefore show only the components and combinations associated with the present invention, so as to provide a clearer description of the basic architecture or method of implementation. The components would be complex in reality. In addition, for ease of explanation, the components shown in the drawings may not represent their actual number, shape, and dimensions; details can be adjusted according to design requirements.

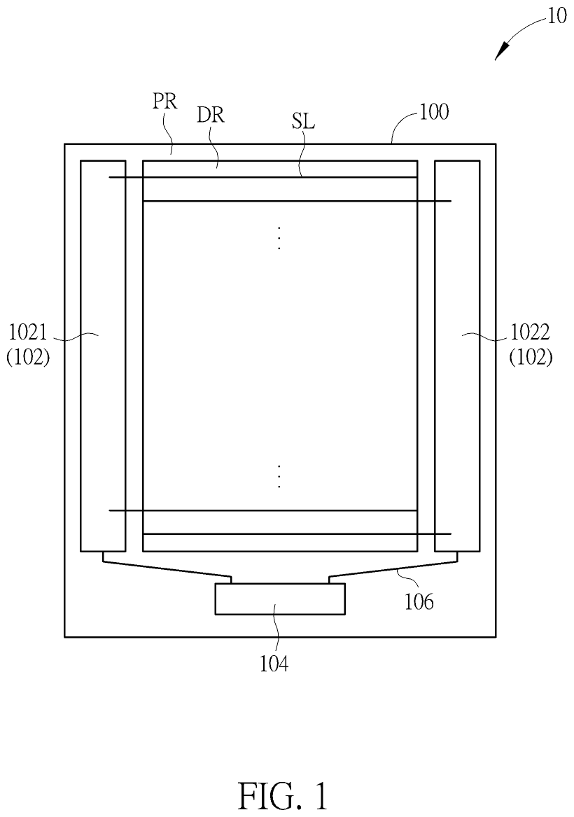

Referring to FIG. 1, it is a schematic diagram illustrating a display panel of a first embodiment of the present invention. A display panel 10 of the present invention can be various types of display panels, such as a liquid crystal display panel, an electrophoretic display panel, an organic light emitting display (OLED) panel, or a micro light emitting diode (micro LED) display panel, but not limited thereto. As shown in FIG. 1, a substrate 100 of the display panel 10 has a surface, and the surface includes a display region DR and a peripheral region PR disposed on at least one side of the display region DR. In this embodiment, the peripheral region PR surrounds the display region DR, but not limited thereto. The substrate 100 may be a rigid substrate such as glass substrate, plastic substrate, quartz substrate or sapphire substrate, or may be a flexible substrate including polyimide (PI) material or polyethylene terephthalate (PET) material, but not limited thereto. The display panel 10 includes a plurality of scan lines SL disposed in the display region DR. For example, the scan lines SL may extend into the display region DR from the peripheral region PR, and the scan lines SL may be electrically connected to sub-pixels in the display region DR.

The display panel 10 may include at least one gate driver circuit 102 disposed in the peripheral region PR, and the gate driver circuit 102 is disposed on one side of the display region DR. The gate driver circuit 102 can be electrically connected to the scan lines SL, and the gate driver circuit 102 can transmit scan signals to the scan lines SL, so as to drive the sub pixels in the display region DR. Besides, the gate driver circuit 102 may be electrically connected to at least one controlling integrated circuit (IC) 104, and the controlling IC 104 may transmit control signals (such as a clock signal, initial signal, and ending signal) to the gate driver circuit 102. The controlling IC 104 may be disposed in the peripheral region PR, but not limited thereto. In this embodiment, the display panel 10 may include two gate driver circuits 1021, 1022 respectively disposed on both sides of the display region DR, but the numbers and locations of the gate driver circuit 102 and the controlling IC 104 are not limited thereto. As shown in FIG. 1, for the adjacent two scan lines SL, one of the scan lines SL may be electrically connected to the gate driver circuit 1021, and the other one of the scan lines SL may be electrically connected to the gate driver circuit 1022.

The circuit structures of the gate driver circuits 1021, 1022 are gate driver on array (GOA), but not limited thereto. In some embodiments, the gate driver circuit 102 may be fabricated as a chip and disposed on the substrate 100, or the gate driver circuit 102 may be fabricated on a flexible or rigid circuit board and electrically connected to connecting pads disposed on the substrate 100, and the connecting pads can be electrically connected to the scan lines SL. For example, the gate driver circuit 102 may include a plurality of control signal lines (such as clock signal lines, an initial signal line, and an ending signal line). The control signal lines may be electrically connected to the controlling IC 104 through traces 106 so that the controlling IC 104 may transmit control signals (such as clock signals, an initial signal, and an ending signal) to the gate driver circuit 102. The components and structure of the gate driver circuit 102 will be described below in detail.

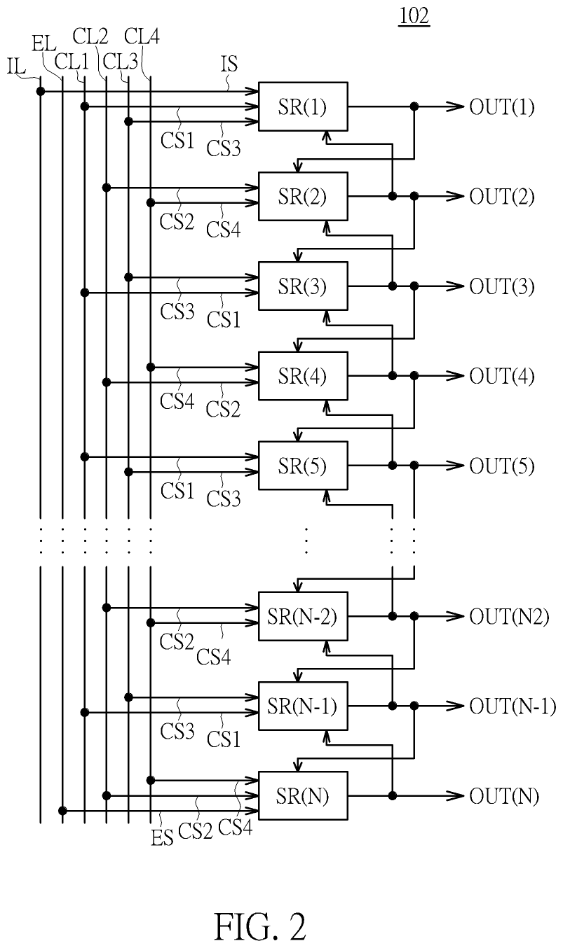

Referring to FIG. 2, it is a schematic diagram illustrating a gate driver circuit of the first embodiment of the present invention. The gate driver circuit 102 of this embodiment includes clock signal lines CL1 to CL4, an initial signal line IL, an ending signal line EL, and a first-level shift register SR(1) to a n^{th}-level shift register SR(N), and N is a positive integer greater than or equal to 5, but not limited thereto. The clock signal lines CL1 to CL4 provide the clock signals CS1-CS4 to the corresponding shift registers SR(1)-SR(N). The first-level shift register SR(1) to the n^{th}-level shift register SR(N) may include GOA circuit structure. Furthermore, N may be a multiple of 4, and the clock signal line CL1 and the clock signal line CL3 respectively provide the clock signal CS1 and the clock signal CS3 to the first-level shift register SR(1), the third-level shift register SR(3), the fifth-level shift register SR(5) . . . the (N−3)^{th}-level shift register SR(N−3), and the (N−1)^{th}-level shift register SR(N−1). The clock signal line CL2 and the clock signal line CL4 respectively provide the clock signal CS2 and the clock signal CS4 to the second-level shift register SR(2), the fourth-level shift register SR(4),the sixth-level shift register SR(6) . . . the (N−2)^{th}-level shift register SR(N−2), and the N^{th}-level shift register SR(N). The number of the clock signal lines of the present invention is not limited to 4.

In addition, the initial signal line IL provides an initial signal IS to the first-level shift register SR(1), and the ending signal line EL provides an ending signal ES to the N^{th}-level shift register SR(N). The gate driver circuit 102 of this embodiment may be applied to forward scanning driving. However, in some embodiments, the gate driver circuit 102 may be applied to reverse scanning driving. When the gate driver circuit 102 is applied to the reverse scanning driving, the N^{th}-level shift register SR(N) may receive the initial signal, and the first-level shift register SR(1) may receive the ending signal, but not limited thereto. The clock signal lines CL1-CL4, the initial signal line IL, and the ending signal line EL may be coupled to one or more than one chip. That is, the clock signals CS1-CS4, the initial signal IS, and the ending signal ES may be provided by this one or more than one chip, such as a driving chip and/or a timing control chip and so on, but not limited thereto.

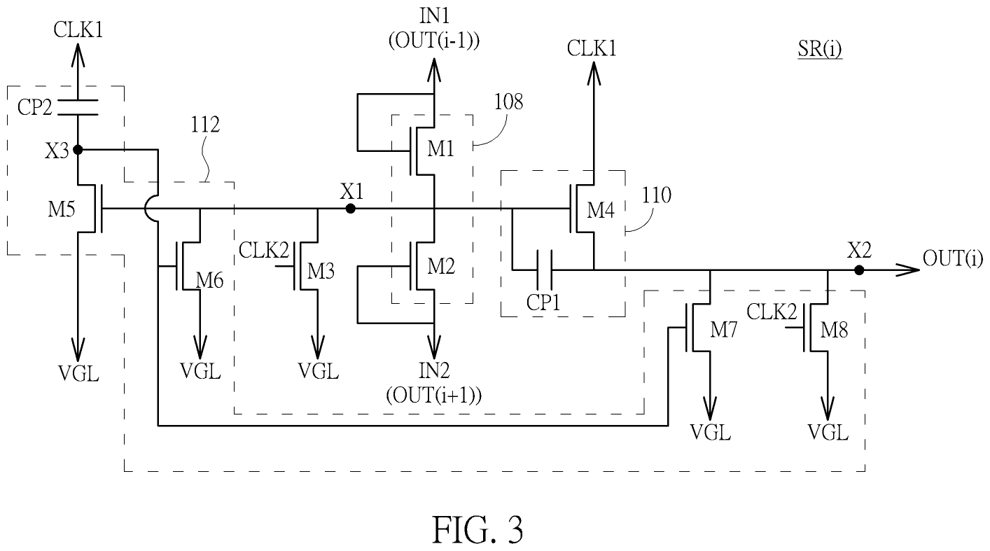

Referring to FIG. 3, it is an equivalent circuit diagram of an i^{th}-level shift register in the gate driver circuit of FIG. 2. The i^{th}-level shift register SR(i) (i is a positive integer greater than or equal to 1, and i can be a positive integer from 1 to N for example) includes a precharge unit 108, a pull-up unit 110, and a pull-down unit 112. One terminal of the precharge unit 108 and one terminal of the pull-up unit 106 are coupled to a first node X1, and a second node X2 at another terminal of the pull-up unit 106 outputs the i^{th}-level scan signal OUT(i) to the corresponding scan line SL. The precharge unit 108 receives a first input signal IN1 and a second input signal IN2 and controls the electric potential of the first node X1 according to the first input signal IN1 or the second input signal IN2. The precharge unit 108 includes a first transistor M1 and a second transistor M2. In this embodiment, the gate driver circuit 102 is a dual directional scanning driving circuit, and in one of the shift registers SR(1)-SR(N), a first terminal of the first transistor M1 receives the first input signal IN1, a gate of the first transistor M1 is coupled to the first terminal of the first transistor M1, and a second terminal of the first transistor M1 is coupled to the first node X1. A first terminal of the second transistor M2 receives the second input signal IN2, a gate of the second transistor M2 is coupled to the first terminal of the second transistor M2, and a second terminal of the second transistor M2 is coupled to the first node X1. In the present invention, the “first terminal” and “second terminal” of the thin film transistor may respectively mean the source electrode and the drain electrode of a thin film transistor, or may respectively mean the drain electrode and the source electrode of a thin film transistor.

If the shift register SR(i) is a first-level shift register (that is, i is 1), then the first input signal IN1 is the initial signal IS, and the second input signal IN2 is a scan signal OUT(i+1) output by the (i+1)^{th}-level shift register SR(i+1) (that is, the second-level scan signal OUT(2)). If the shift register SR(i) is any one of the shift registers from the second-level shift register to the (N−1)^{th}-level shift register (that is, i is any one of integers from 2 to (N−1)), then the first input signal IN1 and the second input signal IN2 respectively are the (i−1)^{th}-level scan signal OUT(i−1) output by the (i−1)^{th}-level shift register SR(i−1) and the (i+1)^{th}-level scan signal OUT(i+1) output by the (i+1)^{th}-level shift register SR(i+1). If the shift register SR(i) is the N^{th}-level shift register (that is, i is N), then the first input signal IN1 is the scan signal OUT(i−1) output by the (i−1)^{th}-level shift register SR(i−1) (that is, the (N−1)^{th}-level scan signal OUT(N−1)), and the second input signal IN2 is the ending signal ES. Thus, the shift registers in the gate driver circuit 102 can sequentially output the scan signals OUT(1)-OUT(N) to the scan lines SL of the display panel 10 from the shift register SR(1) to the shift register SR(N). It should be noted that, when the gate driver circuit 102 is in forward scanning mode, IS can be the initial signal and ES can be the ending signal; when the gate driver circuit 102 is in reverse scanning mode, ES can be the initial signal and IS can be the ending signal.

The pull-up unit 110 and the precharge unit 108 are coupled to the first node X1, the pull-up unit 110 receives a first clock signal CLK1, and the scan signal OUT(i) is output from the second node X2 according to the electric potential of the first node X1 and the first clock signal CLK1. The first clock signal CLK1 can be any one of the clock signals CS1-CS4. In the embodiment where N is a multiple of 4, if i is 1, 5 . . . (N−3), then the first clock signal CLK1 is the clock signal CS1; if i is 2, 6 . . . (N−2), then the first clock signal CLK1 is the clock signal CS2; if i is 3, 7 . . . (N−1), then the first clock signal CLK1 is the clock signal CS3, if i is 4, 8 . . . N, then the first clock signal CLK1 is the clock signal CS4. The pull-up unit 110 includes a fourth transistor M4 and a first capacitor CP1. A gate of the fourth transistor M4 is coupled to the first node X1, a first terminal of the fourth transistor M4 receives the first clock signal CLK1, and a second terminal of the fourth transistor M4 is coupled to the second node X2 and can output the scan signal OUT(i). A first terminal of the first capacitor CP1 is coupled to the first node X1 and the gate of the fourth transistor M4, and a second terminal of the first capacitor CP1 is coupled to the second node X2 and the second terminal of the fourth transistor M4.

In addition, the i^{th}-level shift register SR(i) further includes a third transistor M3, a gate of the third transistor M3 receives a second clock signal CLK2, a first terminal of the third transistor M3 receives a reference electric potential VGL, and a second terminal of the third transistor M3 is coupled to the first node X1. A start time of transmitting the second clock signal CLK2 is after an end time of transmitting the first clock signal CLK1. The reference electric potential VGL can be the gate low voltage (VGL), but not limited thereto. In addition, the second clock signal CLK2 can be any one of the clock signals CS1-CS4. In the embodiment where N is a multiple of 4, if i is 1, 5 . . . (N−3), then the second clock signal CLK2 is the clock signal CS3; if I is 2, 6 . . . (N−2), then the second clock signal CLK2 is the clock signal CS4; if i is 3, 7 . . . (N−1), then the second clock signal CLK2 is the clock signal CS1; if i is 4, 8 . . . N, then the second clock signal CLK2 is the clock signal CS2, but not limited thereto.

In some variant embodiments of the first embodiment, if i is 1, 5 . . . (N−3), then the second clock signal CLK2 is the clock signal CS4; if i is 2, 6 . . . (N−2), then the second clock signal CLK2 is the clock signal CS1; if i is 3, 7 . . . (N−1), then the second clock signal CLK2 is the clock signal CS2; if i is 4, 8 . . . N, then the second clock signal CLK2 is the clock signal CS3.

As shown in FIG. 3, one terminal of the precharge unit 108, one terminal of the pull-up unit 110, and one terminal of the pull-down unit 112 are coupled to the first node X1, and another terminal of the pull-up unit 110 and another terminal of the pull-down unit 112 are coupled to the second node X2. The pull-down unit 112 includes a second capacitor CP2, a fifth transistor M5, a sixth transistor M6, a seventh transistor M7, and an eighth transistor M8. The first transistor M1 to the eighth transistor M8 may be thin film transistors in this embodiment. A first terminal of the second capacitor CP2 receives the first clock signal CLK1. A gate of the fifth transistor M5 is coupled to the first node X1, a first terminal of the fifth transistor M5 receives the reference electric potential VGL, and a second terminal of the fifth transistor M5 is coupled to a second terminal of the second capacitor CP2. A gate of the sixth transistor M6 is coupled to the second terminal of the second capacitor CP2, a first terminal of the sixth transistor M6 receives the reference electric potential VGL, and a second terminal of the sixth transistor M6 is coupled to the first node X1. A gate of the seventh transistor M7 is coupled to the second terminal of the second capacitor CP2, a first terminal of the seventh transistor M7 receives the reference electric potential VGL, and a second terminal of the seventh transistor M7 is coupled to the second node X2. A gate of the eighth transistor M8 receives the second clock signal CLK2, a first terminal of the eighth transistor M8 receives the reference electric potential VGL, and a second terminal of the eighth transistor M8 is coupled to the second node X2.

In some gate driver circuits, each level of the shift registers is electrically connected to the shift registers that are two levels less and/or two levels more than this shift register. Thus, the number of connecting wires between the shift registers of different levels or the times of the connecting wires crossing with each other is increased. However, in the gate driver circuit 102 of this embodiment (as shown in FIGS. 2 and 3), each level of the shift registers SR(i) is electrically connected to the previous level shift register SR(i−1) and/or the subsequent level shift register SR(i+1), or each level of the shift registers SR(i) receives the previous level scan signal OUT(i−1) and/or the subsequent level scan signal OUT(i+1). Therefore, in the gate driver circuit 102 of this embodiment, the number of connecting wires between the shift registers of different levels or the times of the connecting wires required to cross with each other can be reduced, so that the layout of the connecting wires can be simpler, or the space occupied by the connecting wires can be decreased, thereby reducing the width of the peripheral region PR.

In addition, in some gate driver circuits, each level of the shift registers may include thirteen thin film transistors. However, each level of the shift registers SR(i) in this embodiment includes eight thin film transistors. Therefore, the space occupied by the gate driver circuit 102 of this embodiment is relatively small, thus the width of the peripheral region PR can be reduced. In another aspect, when the display panel adopts dual-gate design, the number of shift registers is greater than that of the general display panel, making the space used for disposing the shift registers in the peripheral region PR more stringent. However, since the number of thin film transistors and the area occupied by the shift registers are reduced in this embodiment, the thin film transistors used for outputting scan signals and having larger size (e.g., channel width) can be provided to ensure that the shift registers have sufficient output voltage to turn on thin film transistors of pixels and input the correct voltage.

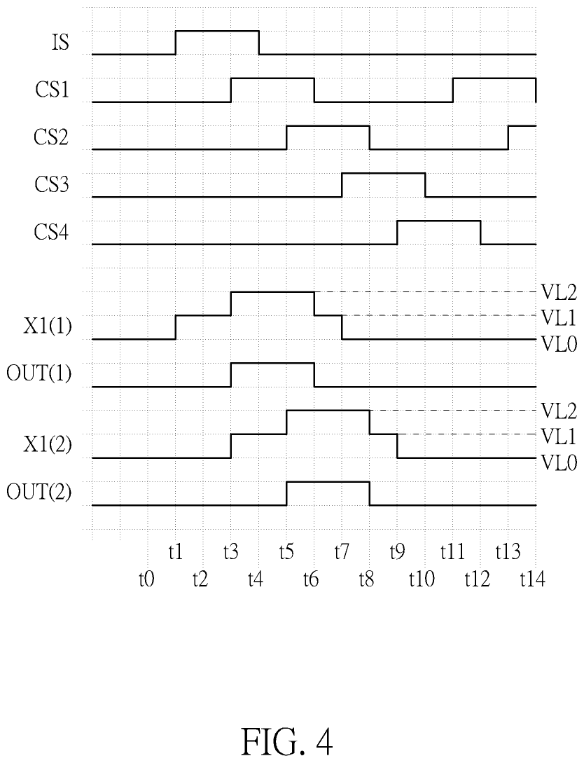

Referring to FIG. 4, it is a timing diagram of the gate drive circuit of FIG. 2. In order to make the drawing more simplified and easy to understand, FIG. 4 shows the timing change of a portion of a frame time, and FIG. 4 shows the timing changes of signals related to the first-level shift register SR(1) and the second-level shift register SR(2). In this embodiment, as shown in FIG. 4 (referring to FIGS. 2 and 3 also), when the initial signal IS rises from low electric potential to high electric potential at time t1, the first transistor M1 of the first-level shift register SR(1) is turned on due to the initial signal IS, and the electric potential of the first node X1(1) is also changed from a reference electric potential VL0 to a first electric potential VL1 according to the initial signal IS (i.e., the first input signal IN1). Although the fourth transistor M4 is turned on due to the first electric potential VL1 of the first node X1(1), the scan signal OUT(1) still remains at low electric potential because the clock signal CS1 is at low electric potential.

At time t3, the fourth transistor M4 is still on, the clock signal CS1 rises from low electric potential to high electric potential, and the electric potential of the first node X1(1) is changed from the first electric potential VL1 to a second electric potential VL2 by the coupling effect of the first capacitor CP1. At this time, the scan signal OUT(1) (or the second node X2(1)) rises from low electric potential to high electric potential, the shift register SR(1) outputs the scan signal OUT(1) to the corresponding scan line SL according to the electric potential of the first node X1(1) and the clock signal CS1, and the electric potential of the first node X1(2) in the second-level shift register SR(2) rises from the reference electric potential VL0 to the first electric potential VL1 due to the scan signal OUT(1). For example, the second electric potential VL2 can be greater than the first electric potential VL1 and the reference electric potential VL0, and the first electric potential VL1 can be greater than the reference electric potential VL0, but not limited thereto.

At time t6, the clock signal CS1 is lowered from high electric potential to low electric potential, so that the electric potential of the first node X1(1) is changed from the second electric potential VL2 to the first electric potential VL1. At the same time, the scan signal OUT(1) (or the second node X2(1)) is lowered from high electric potential to low electric potential, and the shift register SR(1) stops outputting the scan signal OUT(1) to the corresponding scan line SL.

At time t7, the clock signal CS3 rises from low electric potential to high electric potential, and the third transistor M3 in the first-level shift register SR(1) is turned on due to the clock signal CS3, so that the electric potential of the first node X1(1) falls from the first electric potential VL1 to the reference electric potential VL0 to reset the first-level shift register SR(1). In this embodiment, the electric potential of the first node X1(1) does not fall directly from the second electric potential VL2 to the reference electric potential VL0 when the clock signal CS1 drops to low electric potential, and the first node X1(1) remains at the first electric potential VL1 for a period of time (e.g., from the time t6 to the time t7) to extend the operating time of the fourth transistor M4. As a result, the waveform of the signal falls steeply when the time of outputting the scan signal OUT(1) is finished, thereby improving the quality of signal processing.

In another aspect, although the fifth transistor M5 of the first-level shift register SR(1) is turned on due to the high electric potential of the first node X1(1) between the time t1 and the time t7, a third node X3(1) of the first-level shift register SR(1) is maintained at the low potential because one terminal of the fifth transistor M5 receives the reference electric potential VGL, thereby turning off the sixth transistor M6 and the seventh transistor M7.

At time t11, the clock signal CS1 is raised from low electric potential to high electric potential again. At this time, in the first-level shift register SR(1), the third node X3(1) is changed from low electric potential to high electric potential by the coupling effect of the second capacitor CP2, thereby turning on the sixth transistor M6 and the seventh transistor M7. Since one terminal of the sixth transistor M6 receives the reference electric potential VGL, the first node X1(1) can be maintained at the low electric potential (such as the reference electric potential VGL). In addition, since one terminal of the seventh transistor M7 receives the reference electric potential VGL, the second node X2(1) or the scan signal OUT(1) can be maintained at the low electric potential (such as the reference electric potential VGL). In addition, the clock signal CS3 rises from low electric potential to high electric potential again after time t14. At this time, in the first-level shift register SR(1), the eighth transistor M8 is turned on due to the clock signal CS3, and the second node X2(1) or the scan signal OUT(1) can be maintained at the low electric potential (such as the reference electric potential VGL). As a result, abnormal operation of the first-level shift register SR(1) can be prevented after the output of the scan signal OUT(1) is completed.

In the second-level shift register SR(2), the electric potential of the first node X1(1) is changed from the reference electric potential VL0 to the first electric potential VL1 according to the scan signal OUT(1) (i.e., the first input signal IN1) of the first-level shift register SR(1) at the time t3. At the time t5, the clock signal CS2 rises from low electric potential to high electric potential, and the electric potential of the first node X1(2) changes from the first electric potential VL1 to the second electric potential VL2. At this time, the scan signal OUT(2) rises from low electric potential to high electric potential, the shift register SR(2) outputs the scan signal OUT(2) to the corresponding scan line SL, and the first node X1(3) of the third-level shift register SR(3) rises from the reference electric potential VL0 to the first electric potential VL1 due to the scan signal OUT(2).

At time t8, the clock signal CS2 is lowered from high electric potential to low electric potential, so that the electric potential of the first node X1(2) is changed from the second electric potential VL2 to the first electric potential VL1. At the same time, the scan signal OUT(2) drops from high electric potential to low electric potential and causes the shift register SR(2) to stop outputting the scan signal OUT(2) to the corresponding scanning line SL. At time point t9, the clock signal CS4 rises from low electric potential to high electric potential, and the third transistor M3 of the second-level shift register SR(2) is turned on due to the clock signal CS4, so that the electric potential of the first node X1(2) falls from the first electric potential VL1 to the reference electric potential VL0 to reset the second-level shift register SR(2). In addition, after the second-level shift register SR(2) is reset, the sixth transistor M6, the seventh transistor M7, and the eighth transistor M8 in the second-level shift register SR(2) may be used to maintain the scan signal OUT(2) at low electric potential (e.g., the reference electric potential VGL). The operation method of the remaining shift registers SR(3)-SR(N) in the gate driver circuit 102 of this embodiment is similar to the above description, and it is not redundantly described herein.

In some gate driver circuits, each level of the shift registers is electrically connected to the shift registers that are two levels less and/or two levels more than this shift register. In this case, when the first-level shift register and the second-level shift register are electrically connected to the same initial signal line or receive the same initial signal, the precharge times of the first nodes of the first-level and the second-level shift registers will be different, thus causing the waveforms of the scan signals output by the first-level and the second-level shift registers to be different. In order to overcome the above problem, two initial signal lines are required to respectively provide two initial signals to the first-level and the second-level shift registers. The above design will increase the space occupied by the gate driver circuit. However, in the gate driver circuit 102 of this embodiment, each level of the shift registers SR(i) is electrically connected to the previous level shift register SR(i−1) and/or the subsequent level shift register SR(i+1). Therefore, only one initial signal line IL is required to provide the initial signal IS to the first-level shift register SR(1) in the gate driver circuit 102 of this embodiment. Additionally, as shown in FIG. 4, the precharge times of the first node X1(1) of the first-level shift registers SR(1) and the first node X1(2) of the second-level shift register SR(2) are equal (such as two time units), so that the scan signals OUT(1) and OUT(2) output by the first-level and the second-level shift registers SR(1) and SR(2) with the same waveform can be obtained, and the signal processing quality can be further improved.

According to the above description, a driving method of the display panel 10 can be provided by this embodiment. The driving method includes following steps. Firstly, the gate driver circuit 102 is provided, the gate driver circuit 102 includes a plurality of shift registers SR(1)-SR(N), and the i^{th}-level shift register SR(i) includes the precharge unit 108 and the pull-up unit 110. The precharge unit 108 is used for receiving the first input signal IN1 and the second input signal IN2 and controls the electric potential of the first node X1 according to the first input signal IN1 or the second input signal IN2. The precharge unit 108 includes the first transistor M1 and the second transistor M2. The first terminal of the first transistor M1 receives the first input signal IN1, the gate of the first transistor M1 is coupled to the first terminal of the first transistor M1, and the second terminal of the first transistor M1 is coupled to the first node X1. The first terminal of the second transistor M2 receives the second input signal IN2, the gate of the second transistor M2 is coupled to the first terminal of the second transistor M2, and the second terminal of the second transistor M2 is coupled to the first node X1. The pull-up unit 110 and the precharge unit 108 are coupled to the first node X1. The pull-up unit 110 receives the first clock signal CLK1 and outputs the i^{th}-level scan signal OUT(i) from the second node X2 according to the electric potential of the first node X1 and the first clock signal CLK1, and i is a positive integer greater than or equal to 1. Secondly, the initial signal IS is set as the first input signal IN1 and the second-level scan signal OUT(2) output by the second-level shift register SR(2) is set as the second input signal IN2 when i is 1. Thirdly, the (i−1)^{th}-level scan signal OUT(i−1) output by the (i−1)^{th}-level shift register SR(i−1) is set as the first input signal IN1, and the (i+1)^{th}-level scan signal OUT(i+1) output by the (i+1)^{th}-level shift register SR(i+1) is set as the second input signal IN2 when i is any positive integer from 2 to (N−1). As a result, the shift registers SR(1)-SR(N) can sequentially output the scan signals OUT(1)-OUT(N) to the display panel 10.

The gate driver circuit of the present invention is not limited to the aforementioned embodiment. The following description continues to detail other embodiments. To simplify the description and show the difference between other embodiments and the above-mentioned embodiment, identical components in each of the following embodiments are marked with identical symbols, and the identical features will not be redundantly described.

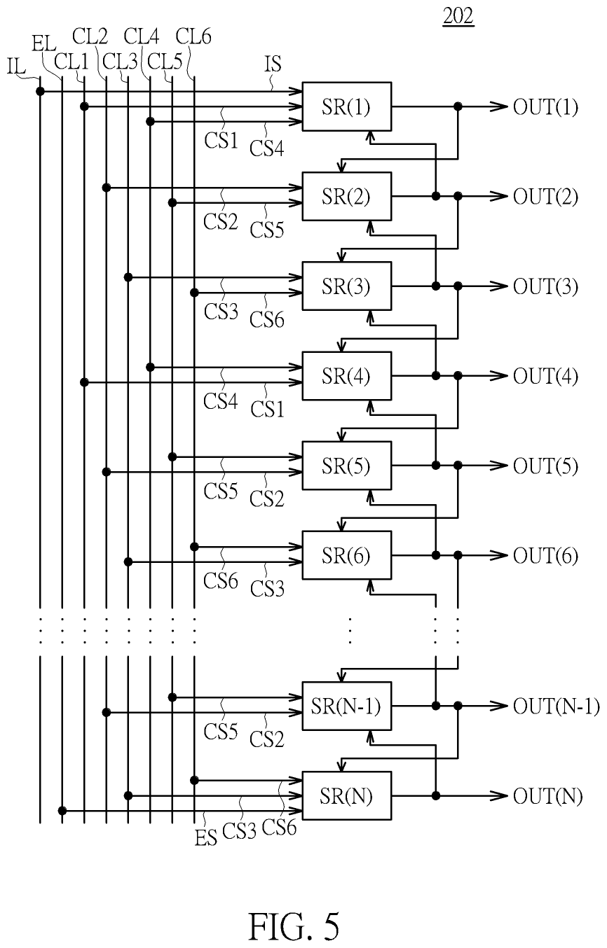

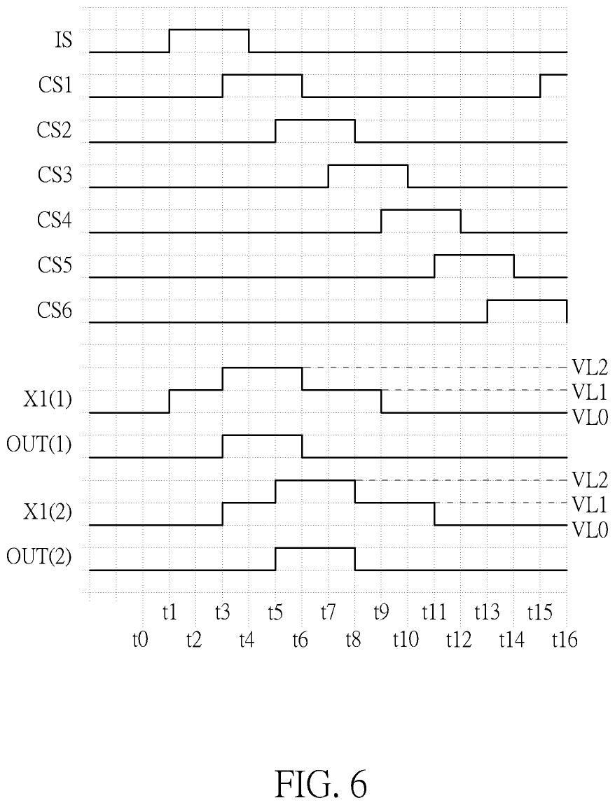

Referring to FIG. 5 and FIG. 6, FIG. 5 is a schematic diagram illustrating a gate driver circuit of a second embodiment of the present invention, and FIG. 6 is a timing diagram of the gate drive circuit of FIG. 5. In order to make the drawing more simplified and easy to understand, FIG. 6 shows the timing change of a portion of a frame time, and FIG. 6 shows the timing changes of signals related to the first-level shift register SR(1) and the second-level shift register SR(2). Different from the first embodiment, the gate driver circuit 202 of this embodiment includes clock signal lines CL1-CL6 as shown in FIG. 5, and N is a positive integer greater than or equal to 7, but not limited thereto. As shown in FIG. 5 and FIG. 3, in the embodiment that N is a multiple of 6, if i is 1, 7 . . . (N−5), then the first clock signal CLK1 is the clock signal CS1; if i is 2, 8 . . . (N−4), then the first clock signal CLK1 is the clock signal CS2; if i is 3, 9 . . . (N−3), then the first clock signal CLK1 is the clock signal CS3, if i is 4, 10 . . . (N−2), then the first clock signal CLK1 is the clock signal CS4; if i is 5, 11 . . . (N−1), then the first clock signal CLK1 is the clock signal CS5; if i is 6, 12 . . . N, then the first clock signal CLK1 is the clock signal CS6. In another aspect, if i is 1, 7 . . . (N−5), then the second clock signal CLK2 is the clock signal CS4; if i is 2, 8 . . . (N−4), then the second clock signal CLK2 is the clock signal CS5; if i is 3, 9 . . . (N−3), then the second clock signal CLK2 is the clock signal CS6; if i is 4, 10 . . . (N−2), then the second clock signal CLK2 is the clock signal CS1; if i is 5, 11 . . . (N−1), then the second clock signal CLK2 is the clock signal CS2; if i is 6, 12 . . . N, then the second clock signal CLK2 is the clock signal CS3.

In some variant embodiments of the second embodiment, if i is 1, 7 . . . (N−5), then the second clock signal CLK2 is the clock signal CS5; if i is 2, 8 . . . (N−4), then the second clock signal CLK2 is the clock signal CS6; if i is 3, 9 . . . (N−3), then the second clock signal CLK2 is the clock signal CS1; if i is 4, 10 . . . (N−2), then the second clock signal CLK2 is the clock signal CS2; if i is 5, 11 . . . (N−1), then the second clock signal CLK2 is the clock signal CS3; if i is 6, 12 . . . N, then the second clock signal CLK2 is the clock signal CS4, but not limited thereto.

In addition, the reset time of the shift register SR(i) in this embodiment is different from that of the first embodiment. As shown in FIG. 6 (referring to FIGS. 3 and 5 also), in the first-level shift register SR(1) of this embodiment, the clock signal CS4 rises from low electric potential to high electric potential at time t9, and the electric potential of the first node X1(1) of the first-level shift register SR(1) falls from the first electric potential VL1 to the reference electric potential VL0 to reset the first-level shift register SR(1). In another aspect, the clock signal CS5 rises from low electric potential to high electric potential at time t11, and the electric potential of the first node X1(2) of the second-level shift register SR(2) falls from the first electric potential VL1 to the reference electric potential VL0 to reset the second-level shift register SR(2). In addition, the remaining operation method, features, and functions of the gate drive circuit 202 of this embodiment may be similar to those of the first embodiment, and they will not be redundantly described herein.

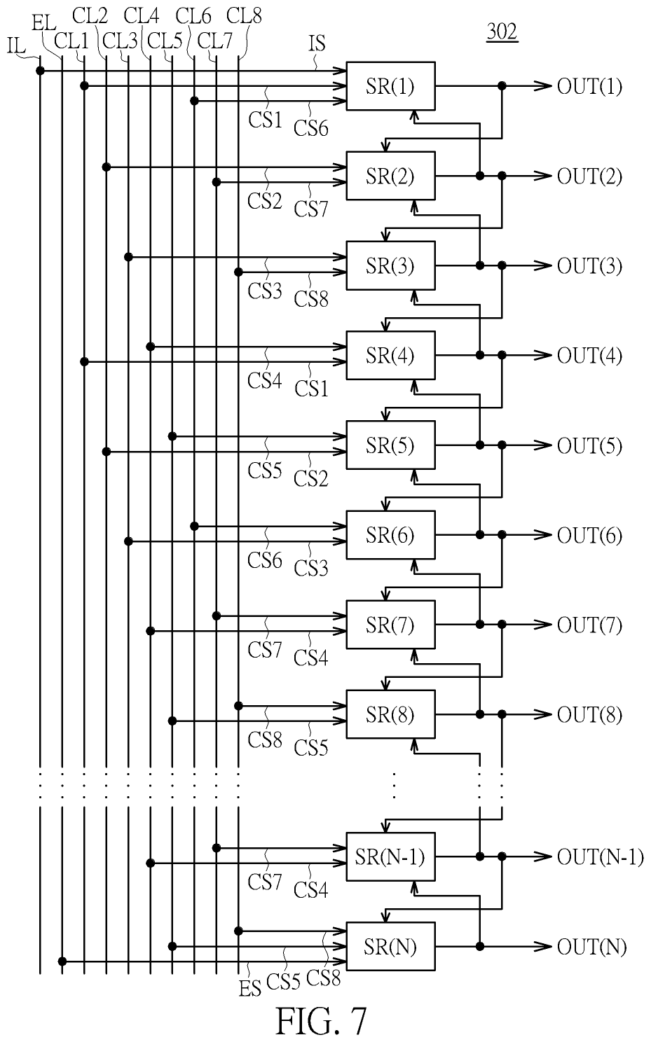

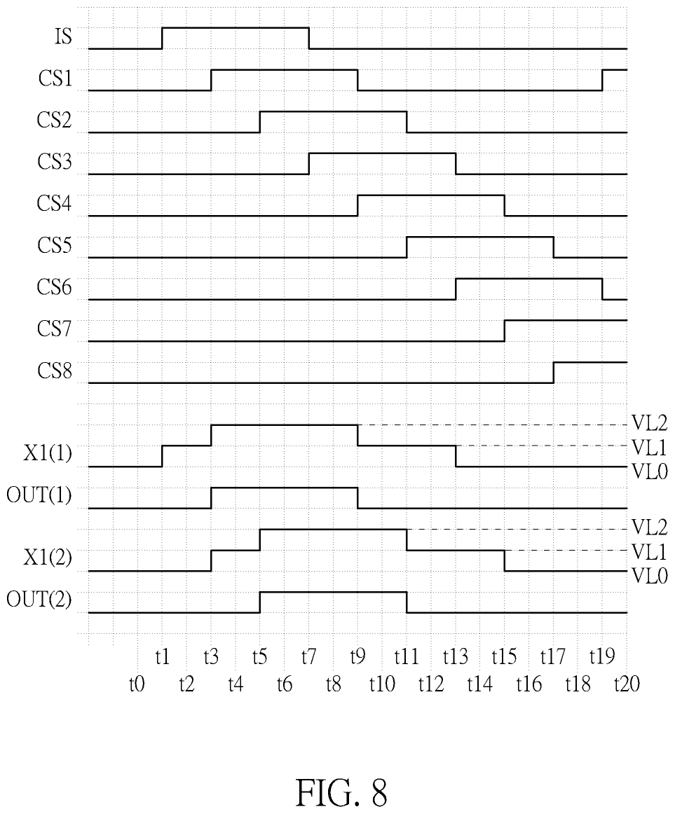

Referring to FIG. 7 and FIG. 8, FIG. 7 is a schematic diagram illustrating a gate driver circuit of a third embodiment of the present invention, and FIG. 8 is a timing diagram of the gate drive circuit of FIG. 7. In order to make the drawing more simplified and easy to understand, FIG. 8 shows the timing change of a portion of a frame time, and FIG. 8 shows the timing changes of signals related to the first-level shift register SR(1) and the second-level shift register SR(2). Different from the first embodiment, the gate driver circuit 302 of this embodiment includes clock signal lines CL1-CL8 as shown in FIG. 7, and N is a positive integer greater than or equal to 9, but not limited thereto. As shown in FIG. 7 and FIG. 3, in the embodiment that N is a multiple of 8, if i is 1, 9 . . . (N−7), then the first clock signal CLK1 is the clock signal CS1; if i is 2, 10 . . . (N−6), then the first clock signal CLK1 is the clock signal CS2; if i is 3, 11 . . . (N−5), then the first clock signal CLK1 is the clock signal CS3; if i is 4, 12 . . . (N−4), then the first clock signal CLK1 is the clock signal CS4; if i is 5, 13 . . . (N−3), then the first clock signal CLK1 is the clock signal CS5; if i is 6, 14 . . . (N−2), then the first clock signal CLK1 is the clock signal CS6; if i is 7, 15 . . . (N−1), then the first clock signal CLK1 is the clock signal CS7; if i is 8, 16 . . . N, then the first clock signal CLK1 is the clock signal CS8.

In another aspect, if i is 1, 9 . . . (N−7), then the second clock signal CLK2 is the clock signal CS6; if i is 2, 10 . . . (N−6), then the second clock signal CLK2 is the clock signal CS7; if i is 3, 11 . . . (N−5), then the second clock signal CLK2 is the clock signal CS8; if i is 4, 12 . . . (N−4), then the second clock signal CLK2 is the clock signal CS1; if i is 5, 13 . . . (N−3), then the second clock signal CLK2 is the clock signal CS2; if i is 6, 14 . . . (N−2), then the second clock signal CLK2 is the clock signal CS3; if i is 7, 15 . . . (N−1), then the second clock signal CLK2 is the clock signal CS4; if i is 8, 16 . . . N, then the second clock signal CLK2 is the clock signal CSS, but not limited thereto.

In some variant embodiments of the third embodiment, if i is 1, 9 . . . (N−7), then the second clock signal CLK2 is the clock signal CSS; if i is 2, 10 . . . (N−6), then the second clock signal CLK2 is the clock signal CS6; if i is 3, 11 . . . (N−5), the second clock signal CLK2 is the clock signal CS7; if i is 4, 12 . . . (N−4), then the second clock signal CLK2 is the clock signal CS8; if i is 5, 13 . . . (N−3), then the second clock signal CLK2 is the clock signal CS1; if i is 6, 14 . . . (N−2), then the second clock signal CLK2 is the clock signal CS2; if i is 7, 15 . . . (N−1), then the second clock signal CLK2 is the clock signal CS3; if i is 8, 16 . . . N, then the second clock signal CLK2 is the clock signal CS4.

As shown in FIG. 8 (referring to FIGS. 3 and 7 also), the electric potential of the first node X1(1) of the first-level shift register SR(1) changes from the reference electric potential VL0 to the first electric potential VL1 when the initial signal IS rises from low electric potential to high electric potential at time t1. At time t3, the clock signal CS1 rises from low electric potential to high electric potential, and the electric potential of the first node X1(1) changes from the first electric potential VL1 to the second electric potential VL2. At this time, the scan signal OUT(1) rises from low electric potential to high electric potential, the shift register SR(1) outputs the scan signal OUT(1) to the corresponding scan line SL, and the first node X1(2) of the second-level shift register SR(2) rises from the reference electric potential VL0 to the first electric potential VL1 due to the scan signal OUT(1).

At time t9, the clock signal CS1 is lowered from high electric potential to low electric potential, and the electric potential of the first node X1(1) is changed from the second electric potential VL2 to the first electric potential VL1. At the same time, the scan signal OUT(1) drops from high electric potential to low electric potential, which causes the shift register SR(1) to stop outputting the scan signal OUT(1) to the corresponding scan line SL. At time t13, the clock signal CS6 rises from low electric potential to high electric potential, and the electric potential of the first node X1(1) of the first-level shift register SR(1) falls from the first electric potential VL1 to the reference electric potential VL0 to reset the first-level shift register SR(1).

In the second-level shift register SR(2), the electric potential of the first node X1(2) changes from the reference electric potential VL0 to the first electric potential VL1 at time t3. At time t5, the clock signal CS2 rises from low electric potential to high electric potential, and the electric potential of the first node X1(2) changes from the first electric potential VL1 to the second electric potential VL2. At this time, the scan signal OUT(2) rises from low electric potential to high electric potential, the shift register SR(2) outputs the scan signal OUT(2) to the corresponding scan line SL, and the first node X1(3) of the third-level shift register SR(3) rises from the reference electric potential VL0 to the first electric potential VL1 due to the scan signal OUT(2).

At time t11, the clock signal CS2 is lowered from high electric potential to low electric potential, so that the electric potential of the first node X1(2) is changed from the second electric potential VL2 to the first electric potential VL1. At the same time, the scan signal OUT(2) drops from high electric potential to low electric potential, which causes the shift register SR(2) to stop outputting the scan signal OUT(2) to the corresponding scanning line SL. At time t15, the clock signal CS7 rises from the low electric potential to high electric potential, and the electric potential of the first node X1(2) of the second-level shift register SR(2) falls from the first electric potential VL1 to the reference electric potential VL0 to reset the second-level shift register SR(2). The operation method of the remaining shift registers SR(3)-SR(N) in the gate driver circuit 302 of this embodiment is similar to the above description, and it will not be redundantly described herein. In addition, the remaining features and functions of the gate driver circuit 302 of this embodiment can be similar to those of the first embodiment, and they will not be redundantly described herein.

To sum up, in the gate driver circuit and the driving method of the display panel of the present invention, each level of the shift registers is electrically connected to the shift register of the previous level and/or the shift register of the subsequent level, or each level of the shift registers receives the scan signal of the previous level and/or the scan signal of the subsequent level. Therefore, in the gate driver circuit of the present invention, the number of connecting wires between the shift registers of different levels or the times of the connecting wires required to cross with each other can be reduced, so that the layout of the connecting wires can be simpler, or the space occupied by the connecting wires can be decreased, thereby reducing the width of the peripheral region. In addition, each level of the shift registers in the present invention includes eight thin film transistors. Therefore, the space occupied by the gate driver circuit of the present invention is relatively small, thus the width of the peripheral region can be reduced.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A gate driver circuit used for driving a display panel, the gate driver circuit comprising:
a plurality of shift registers sequentially outputting a plurality of scan signals to the display panel, wherein an i^{th}-level shift register comprises:
a precharge unit used for receiving a first input signal and a second input signal and controlling an electric potential of a first node according to the first input signal or the second input signal, wherein the precharge unit comprises:
a first transistor, wherein a first terminal of the first transistor receives the first input signal, a gate of the first transistor is coupled to the first terminal of the first transistor, and a second terminal of the first transistor is coupled to the first node; and
a second transistor, wherein a first terminal of the second transistor receives the second input signal, a gate of the second transistor is coupled to the first terminal of the second transistor, and a second terminal of the second transistor is coupled to the first node; and
a pull-up unit, wherein the pull-up unit and the precharge unit are coupled to the first node, the pull-up unit receives a first clock signal and outputs an i^{th}-level scan signal from a second node according to the electric potential of the first node and the first clock signal, and i is a positive integer greater than or equal to 1.

2. The gate driver circuit of claim 1, wherein the i^{th}-level shift register further comprises a third transistor, a gate of the third transistor receives a second clock signal, a first terminal of the third transistor receives a reference electric potential, a second terminal of the third transistor is coupled to the first node, and a start time of transmitting the second clock signal is after an end time of transmitting the first clock signal.

3. The gate driver circuit of claim 1, wherein the first input signal is a (i−1)^{th}-level scan signal output by a (i−1)^{th}-level shift register, and the second input signal is a (i+1)^{th}-level scan signal output by a (i+1)^{th}-level shift register when i is any positive integer from 2 to (N−1), wherein N is a positive integer greater than 2.

4. The gate driver circuit of claim 1, wherein the first input signal is an initial signal, and the second input signal is a second-level scan signal output by a second-level shift register when i is 1.

5. The gate driver circuit of claim 1, wherein the pull-up unit comprises:
a fourth transistor, wherein a gate of the fourth transistor is coupled to the first node, a first terminal of the fourth transistor receives the first clock signal, and a second terminal of the fourth transistor is coupled to the second node; and
a first capacitor, wherein a first terminal of the first capacitor is coupled to the first node, and a second terminal of the first capacitor is coupled to the second node.

6. The gate driver circuit of claim 1, wherein the i^{th}-level shift register further comprises a pull-down unit, and the pull-down unit comprises:
a second capacitor, wherein a first terminal of the second capacitor receives the first clock signal;
a fifth transistor, wherein a gate of the fifth transistor is coupled to the first node, a first terminal of the fifth transistor receives the reference electric potential, and a second terminal of the fifth transistor is coupled to a second terminal of the second capacitor;
a sixth transistor, wherein a gate of the sixth transistor is coupled to the second terminal of the second capacitor, a first terminal of the sixth transistor receives the reference electric potential, and a second terminal of the sixth transistor is coupled to the first node;
a seventh transistor, wherein a gate of the seventh transistor is coupled to the second terminal of the second capacitor, a first terminal of the seventh transistor receives the reference electric potential, and a second terminal of the seventh transistor is coupled to the second node; and
an eighth transistor, wherein a gate of the eighth transistor receives a second clock signal, a first terminal of the eighth transistor receives the reference electric potential, and a second terminal of the eighth transistor is coupled to the second node,
wherein a start time of transmitting the second clock signal is after an end time of transmitting the first clock signal.

7. A driving method of a display panel, comprising:
providing a gate driver circuit, the gate driver circuit comprising a plurality of shift registers, wherein an i^{th}-level shift register comprises:
a precharge unit used for receiving a first input signal and a second input signal and controlling an electric potential of a first node according to the first input signal or the second input signal, wherein the precharge unit comprises:
a first transistor, wherein a first terminal of the first transistor receives the first input signal, a gate of the first transistor is coupled to the first terminal of the first transistor, and a second terminal of the first transistor is coupled to the first node; and
a second transistor, wherein a first terminal of the second transistor receives the second input signal, a gate of the second transistor is coupled to the first terminal of the second transistor, and a second terminal of the second transistor is coupled to the first node; and
a pull-up unit, wherein the pull-up unit and the precharge unit are coupled to the first node, the pull-up unit receives a first clock signal and outputs an i^{th}-level scan signal from a second node according to the electric potential of the first node and the first clock signal, and i is a positive integer greater than or equal to 1;
setting an initial signal as the first input signal, and setting a second-level scan signal output by a second-level shift register as the second input signal when i is 1; and
setting a (i−1)^{th}-level scan signal output by a (i−1)^{th}-level shift register as the first input signal and setting a (i+1)^{th}-level scan signal output by a (i+1)^{th}-level shift register as the second input signal when i is any positive integer from 2 to (N−1), and the shift registers sequentially output a plurality of scan signals to the display panel, wherein N is a positive integer greater than 2.

8. The driving method of the display panel of claim 7, wherein the i^{th}-level shift register further comprises a third transistor, a gate of the third transistor receives a second clock signal, a first terminal of the third transistor receives a reference electric potential, a second terminal of the third transistor is coupled to the first node, and a start time of transmitting the second clock signal is after an end time of transmitting the first clock signal.

9. The driving method of the display panel of claim 7, wherein the pull-up unit comprises:
a fourth transistor, wherein a gate of the fourth transistor is coupled to the first node, a first terminal of the fourth transistor receives the first clock signal, and a second terminal of the fourth transistor is coupled to the second node; and
a first capacitor, wherein a first terminal of the first capacitor is coupled to the first node, and a second terminal of the first capacitor is coupled to the second node.

10. The driving method of the display panel of claim 7, wherein the i^{th}-level shift register further comprises a pull-down unit, and the pull-down unit comprises:
a second capacitor, wherein a first terminal of the second capacitor receives the first clock signal;
a fifth transistor, wherein a gate of the fifth transistor is coupled to the first node, a first terminal of the fifth transistor receives the reference electric potential, and a second terminal of the fifth transistor is coupled to a second terminal of the second capacitor;
a sixth transistor, wherein a gate of the sixth transistor is coupled to the second terminal of the second capacitor, a first terminal of the sixth transistor receives the reference electric potential, and a second terminal of the sixth transistor is coupled to the first node;
a seventh transistor, wherein a gate of the seventh transistor is coupled to the second terminal of the second capacitor, a first terminal of the seventh transistor receives the reference electric potential, and a second terminal of the seventh transistor is coupled to the second node; and
an eighth transistor, wherein a gate of the eighth transistor receives a second clock signal, a first terminal of the eighth transistor receives the reference electric potential, and a second terminal of the eighth transistor is coupled to the second node,
wherein a start time of transmitting the second clock signal is after an end time of transmitting the first clock signal.
